(19) United States
(12) Patent Application Publication
(10) Pub. No.: US 2011/0110037 A1
(43) Pub. Date: May 12, 2011

(54) DRIVER MODULE STRUCTURE

(76) Inventors: Toshiya Yamaguchi, Kagoshima (JP); Shigeo Yumoto, Kagoshima (JP); Hirofumi Kamikokuryou, Kagoshima (JP); Keita Yamamoto, Kagoshima (JP)

(21) Appl. No.: 12/864,644

(22) PCT Filed: Jan. 7, 2009
(86) PCT No.: PCT/JP2009/000032

§ 371 Date: Jul. 26, 2010

(30) Foreign Application Priority Data
Feb. 1, 2008 (JP) 2008-022341

(51) Int. Cl. H05K 7/20

(52) U.S. Cl. 361/692

(57) ABSTRACT

Provided is a driver module structure capable of ensuring high reliability.

A PDP driver device 1 includes: a flexible substrate 2 having an interconnect pattern; a semiconductor device 3 placed on the flexible substrate 2; and a heat dissipating body 4 having a recess 41 configured to accommodate the semiconductor device 3. The heat dissipating body 4 is provided with four grooves 8 as airflow paths that connect a space in the recess 41 to the outside, and the grooves 8 have a substantially V-shaped cross section.

### TECHNICAL FIELD

The present invention relates to driver module structures having a flexible substrate on which a semiconductor device is placed, and a heat dissipating body for dissipating heat that is generated by the semiconductor device.

### BACKGROUND ART

Semiconductor devices for controlling display devices such as flat displays are placed on flexible substrates, and are used as driver modules in the display devices. One known example of driver modules is described in Patent Document 1.

The driver module structure described in Patent Document 1 includes a flexible substrate on which a semiconductor device is placed, and a heat dissipating body having a recess that forms a space for accommodating the semiconductor device, and the flexible substrate has a through hole that connects this space to the outside. This through hole allows air in the space formed by the recess to escape to the outside. Since the through hole is provided in the flexible substrate, the air in the space of the recess is allowed to flow to the outside even if the air expands or is compressed by heat from the semiconductor device. This can prevent the flexible substrate from being subjected to stress.

In the driver module structure of Patent Document 1, the through hole needs to be provided in the flexible substrate, which limits the layout of an interconnect pattern formed on the flexible substrate.

Patent Document 2 describes a driver module structure capable of connecting the space in a recess of a heat dissipating body to the outside without providing any through hole in a flexible substrate.

In an image display device described in Patent Document 2, a groove, which connects the outer periphery of a heat dissipating plate to a recess, is formed as an airflow path in the heat dissipating plate.

### CITATION LIST

### Patent Document

PATENT DOCUMENT 1: Japanese Published Patent Application No. 2005-327850
PATENT DOCUMENT 2: Japanese Published Patent Application No. 2007-333838

### SUMMARY OF THE INVENTION

### Technical Problem

In the heat dissipating plate described in Patent Document 2, air in the recess is allowed to flow to the outside through the groove that connects the recess to the outer periphery of the heat dissipating plate. However, grease is placed in the recess in order to ensure adhesion between a semiconductor device and the heat dissipating plate, and to transfer heat from the semiconductor device to the heat dissipating plate, and this grease can block the groove.

The reason why the grease can block the groove is as follows. When bonding the flexible substrate, which has the semiconductor device placed thereon, to the heat dissipating plate, the grease is placed in the recess of the heat dissipating plate, and then the flexible substrate is placed over the heat dissipating plate with the semiconductor device being aligned with the recess. Thus, if the grease is unevenly placed in the recess in terms of the amount and the position, the grease can be spread up to the inlet of the groove and can enter the groove, as the semiconductor device is inserted into the recess.

In such a case, the grease blocks the groove, and the groove no longer functions as an airflow path, whereby the flexible substrate is subjected to stress by expansion and compression of the air in the recess. In particular, if the air in the recess expands, the space in the recess also expands, bending the flexible substrate in a curved shape. This separates or delaminates the semiconductor device placed on the flexible substrate from the recess, whereby heat from the semiconductor device can no longer be transferred to the heat dissipating plate. Thus, the temperature of the semiconductor device increases rapidly, which can eventually damage the semiconductor device, resulting in malfunctions.

It is an object of the present invention to provide a driver module structure capable of ensuring high reliability against heat generation of a semiconductor device and changes in ambient temperature.

### Solution to the Problem

A driver module structure of the present invention includes: a flexible substrate having an interconnect pattern; a semiconductor device placed on the flexible substrate; and a heat dissipating body having a recess configured to accommodate the semiconductor device, wherein the heat dissipating body is provided with at least two airflow paths that connect a space in the recess to outside.

### Advantages of the Invention

According to the driver module structure of the present invention, even if one airflow path is blocked by grease or the like, air in the recess can flow to the outside through another airflow path. This enables the air in the recess to reliably flow to the outside even if the air in the recess expands or is compressed by heat generated by the semiconductor device. Thus, the present invention is capable of ensuring high reliability against temperature changes.

### BRIEF DESCRIPTION OF THE DRAWINGS

FIG. 1 is an exploded perspective view of a PDP driver device as an example of a driver module according to a first embodiment of the present invention.

FIG. 2 is a cross-sectional view of the PDP driver device of FIG. 1.

FIG. 3 is a diagram showing an inner peripheral wall of a recess of a heat dissipating body as viewed from the inside of the recess.

FIG. 4 is a perspective view of a PDP drive device as an example of a driver module according to a second embodiment of the present invention.

FIG. 5 is a perspective view of a PDP drive device as an example of a driver module according to a third embodiment of the present invention.

### DESCRIPTION OF REFERENCE CHARACTERS

1 PDP Driver Device
2 Flexible Substrate
3 Semiconductor Device
4, 4x, 4y Heat Dissipating Body
5, 6 Electrode
7 Resin
8, 8x, 8y Groove
8a Lower End
9 Grease
41 Recess
41a Bottom Surface
42 Bonding Surface
43 Region
81 First Groove
82 Second Groove

### DESCRIPTION OF EMBODIMENTS

According to a first invention of the present application, a driver module structure includes: a flexible substrate having an interconnect pattern; a semiconductor device placed on the flexible substrate; and a heat dissipating body having a recess configured to accommodate the semiconductor device, wherein the heat dissipating body is provided with at least two airflow paths that connect a space in the recess to outside.

In the driver module structure of the present invention, the recess formed in the heat dissipating body is provided with at least two airflow paths that connect the space in the recess to the outside. This allows the air in the recess to flow to the outside through another airflow path, even if one airflow path is blocked by grease or the like, and/or dust or the like enters the one airflow path from the outside. Thus, air in the space of the recess can reliably flow to the outside even if the air in the recess expands or is compressed by heat generated by the semiconductor device.

According to a second invention of the present application, in the first invention, the at least two airflow paths are positioned so as to face each other on an inner peripheral surface of the recess.

In the second invention, even if the grease spreads unevenly to one side and blocks one of the two airflow paths, the air in the recess can flow to the outside through the other airflow path, which faces the one airflow path on the inner peripheral wall, whereby reliability can be increased.

According to a third invention of the present application, in the first or second invention, the airflow paths are grooves having a substantially V-shaped cross section.

In the third invention, since the airflow paths are the grooves having a substantially V-shaped cross section, lower ends of the grooves are narrower than upper ends thereof. This can reduce the possibility that the grease may enter the grooves as it is spread over a bottom surface of the recess.

### First Embodiment

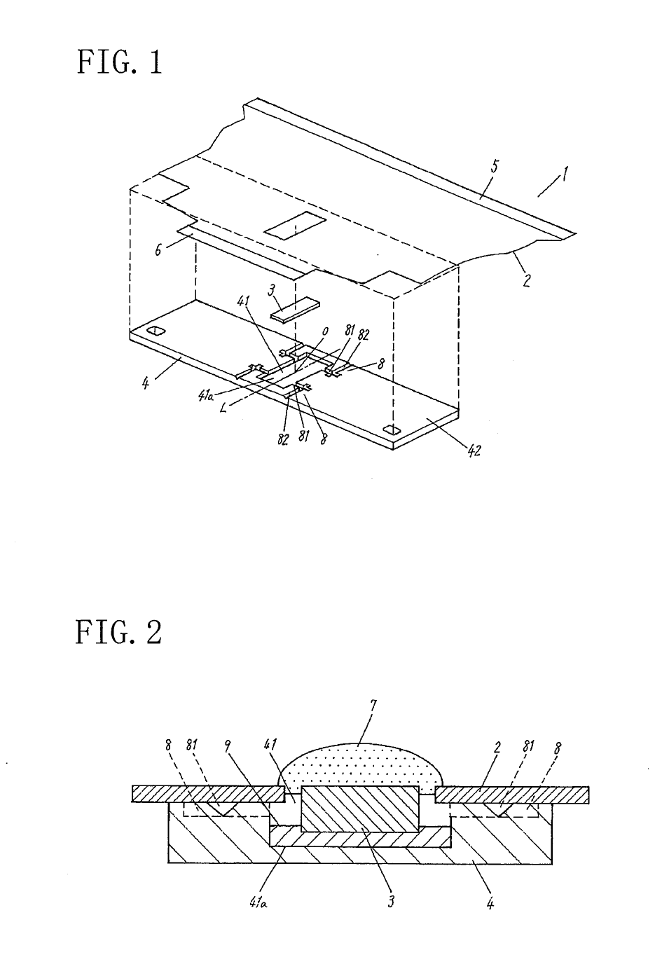

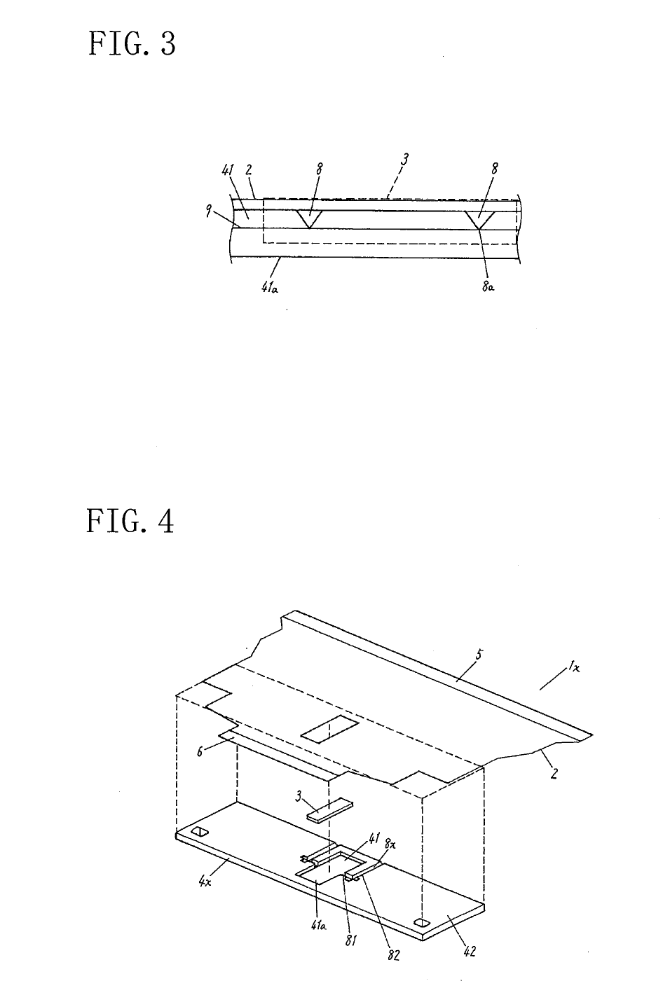

The configuration of a driver module according to a first embodiment of the present invention will be described with reference to FIGS. 1-2 by using a plasma display panel (hereinafter referred to as “PDP”) driver device as an example. FIG. 1 is an exploded perspective view of the PDP driver device as an example of the driver module of the first embodiment of the present invention. FIG. 2 is a cross-sectional view of the PDP driver device of FIG. 1. FIG. 3 is a diagram showing an inner peripheral wall of a recess in a heat dissipating body as viewed from the inside of the recess.

As shown in FIGS. 1-2, the PDP driver device 1 includes a flexible substrate 2, a semiconductor device 3 that is placed on the flexible substrate 2, and a heat dissipating body 4 that is attached to the flexible substrate 2.

The flexible substrate 2 is made of a flexible plastic film. An electrode 5 connecting to a PDP is formed at one end of the flexible substrate 2, and an electrode 6 connecting to a control substrate (not shown) is formed at the other end thereof. The electrodes 5, 6 are connected to the semiconductor device 3 via an interconnect pattern (not shown).

The electrode 5 of the flexible substrate 2 is connected to an electrode of the PDP via an anisotropic conductive film, anisotropic conductive paste, or the like. The electrode 6 of the flexible substrate 2 is connected to an electrode of the control substrate by soldering or the like.

An opening is formed in a central portion of the flexible substrate 2 in order to place the semiconductor substrate 3 on the flexible substrate 2. The interconnect pattern located around the opening is exposed and connected to an electrode of the semiconductor device 3 to electrically connect the semiconductor device 3 to the electrodes 5, 6.

In the first embodiment, the semiconductor device 3 is an integrated circuit (IC) for controlling display of the PDP. The semiconductor device 3 is positioned in the opening formed in the central portion of the flexible substrate 2. The semiconductor device 3 is electrically connected to the interconnect pattern by exposing the interconnect pattern located around the opening only on one side of the flexible substrate 2, and bringing the electrode of the semiconductor device 3 into contact with the exposed interconnect pattern. After the semiconductor device 3 is connected to the flexible substrate 2, the semiconductor device 3 is sealed with a resin 7 (see FIG. 2) to fix the semiconductor device 3 to the flexible substrate 2.

The heat dissipating body 4 is an aluminum plate having a rectangular shape as viewed in plan, and a recess 41 configured to accommodate the semiconductor device 3 is formed in a central portion of the heat dissipating body 4. The recess 41 has grooves 8 having a substantially V-shaped cross section, and connecting the space in the recess 41 to the outside. The grooves 8 function as airflow paths that allow the air in the space in the recess 41, which is formed when the heat dissipating body 4 is bonded to the flexible substrate 2, to flow to the outside. Each groove 8 is formed by a first groove 81 and a second groove 82 so as to have a substantially L shape as viewed in plan.

The first groove 81 is formed so as to extend along the longitudinal direction of the heat dissipating body 4, with one end of the first groove 81 connected to the recess 41, and the other end thereof connected to the second groove 82. Note that the first groove 81 may be extended from its connecting portion with the second groove 82. The second groove 82 is formed so as to extend at right angles to the first groove 81, namely along the lateral direction of the heat dissipating body 4, with one end of the second groove 82 connected to the first groove 81, and the other end thereof connected to the outside. Note that the second groove 82 may also be extended from its connecting portion with the first groove 81.

The grooves 8 are formed so that one ends of the first grooves 81 are connected to the two longer sides of the rectangular recess 41, at two positions on each longer side, namely at four positions in total. Specifically, two pairs of grooves 8, which are located at diagonally opposite positions with respect to the center O of the recess 41, are positioned symmetrically about the point (the center O), and the grooves 8, which face each other with a longitudinal central axis L (extending through the center O of the recess 41) therebetween, are positioned symmetrically about the line (the central axis L). That is, the grooves 8 are positioned so as to face each other on the inner peripheral wall of the recess 41.

The grooves 8 can be formed by press working, namely by pressing a die, having a protruding pattern of substantially L-shaped four grooves 8, against the heat dissipating body having only the recess 41 formed therein. Since the grooves 8 have a substantially V-shaped cross section, the pattern is formed so as to have a substantially V-shaped apex. The use of such a pattern facilitates formation of the grooves 8 even when the grooves 8 having a great depth are desired.

As shown in FIG. 2, grease 9, such as a silicone oil compound, is placed as a heat transfer member in the recess 41 of the heat dissipating body 4 in order to enhance adhesion between the inner surface of the recess 41 and the semiconductor device 2, and to increase heat dissipation.

The PDP driver device of the first embodiment of the present invention configured as described above will be described with respect to a state during a manufacturing process and a state when the PDP driver device is in use, with reference to the figures.

With the opening of the recess 41 of the heat dissipating body 4 facing upward, an appropriate amount of grease 9 is placed in the recess 41. Then, with the semiconductor device 3 on the flexible substrate 2 facing downward, the semiconductor device 3 is aligned with the recess 41, and the flexible substrate 2 is placed over the heat dissipating body 4.

Since a double-sided adhesive tape is attached in advance to the entire bonding surface 42 other than the opening portion of the recess 41 of the heat dissipating body 4, the heat dissipating body 4 and the flexible substrate 2 can be bonded together in close contact with each other. Since screws (not shown) are inserted through the flexible substrate 2 and into the heat dissipating body 4, the flexible substrate 2 can be more firmly fixed to the heat dissipating body 4.

As the semiconductor device 3 is inserted in the recess 41, the grease 9 located between the semiconductor device 3 and a bottom surface 41a of the recess 41 can be spread unevenly depending on a variation in the amount of grease 9 and/or the position of the grease 9 in the recess 9. The grease 9 thus spread can enter at least one of the grooves 8.

Even if only a small amount of grease 9 enters at least one of the grooves 8, dust can adhere to the grease 9 in the at least one of the grooves 8 if the PDP driver device 1 is used in an environment where dust can enter the grooves 8 from the outside. In this case, the dust can gradually accumulate, and eventually block the grooves 8.

Since the grooves 8 have a V-shaped cross section in the first embodiment, lower ends 8a of the grooves 8 have a smaller width than that of upper ends thereof, as shown in FIG. 3. This can reduce the possibility that the grease 9 may enter the grooves 8 as it is spread over the bottom surface 41a of the recess 41.

The grooves 8 are provided so as to extend from the four positions on the inner peripheral surface of the recess 41 to the outside. Thus, even if a maximum of three grooves 3 are completely blocked by a large amount of grease 9, the remaining one groove 8 can function as an airflow path.

Such uneven spreading of the grease 9 normally occurs in one direction. Thus, if the heat dissipating body 4 has at least two grooves 8, there is a low probability that the grease 9 will enter and block the two grooves 8 and/or dust will block the grooves 8. If these two grooves (the airflow paths) 8 are provided at two positions on the inner peripheral surface of the recess 41 so as to face each other, there is a lower probability that the grease 9, which is spread in one direction, is spread in the other direction, namely the opposite direction as well. Thus, in the case where two grooves 8 are provided in the heat dissipating body 4, it is desirable that the two grooves 8 be positioned so as to face each other on the inner peripheral wall of the recess 41. In the first embodiment, the grooves 8 are provided so as to extend radially outward in four directions from the recess 41. If the grease 9 is spread in four directions, it means that the grease 9 is spread uniformly in the recess 41, and thus there is a very low probability that all of the four grooves 8 are blocked. Accordingly, by providing the grooves 8 that extend radially outward in four directions from the recess 41, the grooves 8 reliably serve as airflow paths, thereby reliably allowing the air in the space of the recess 41 to flow to the outside even if the air in the recess 41 expands or is compressed by heat generated by the semiconductor device 3.

Since the air in the space of the recess 41 is reliably allowed to flow to the outside, the flexible substrate 2 is not bent even if the air thermally expands in the recess 41 closed by the flexible substrate 2. Thus, adhesion between the semiconductor device 3 and the heat dissipating body 4 can be ensured. Since the flexible substrate 2 can be prevented from being subjected to stress due to the thermal expansion, the semiconductor device 3 does not delaminate from the interconnect pattern. Thus, the PDP driver device 1 of the first embodiment ensures high reliability against heat generation of the semiconductor device 3 and changes in ambient temperature.

For example, if the PDP driver device 1 is used such that that the electrode 5 connected to the PDP faces upward and the electrode 6 connected to the control substrate faces downward, the grease 9 in the recess 41 can move downward by its own weight, and can enter and block the lower grooves 31. However, since the upper grooves 8 can reliably serve as airflow paths, high reliability can be maintained. The same applies to the case where the PDP driver device 1 is used such that one ends of the electrodes 5, 6 face upward and the other ends thereof face downward.

### Second Embodiment

A PDP driver device according to a second embodiment of the present invention will be described with reference to FIG. 4. FIG. 4 is a perspective view of the PDP driver device as an example of a driver module according to the second embodiment of the present invention. Note that, in FIG. 4, components having the same configuration as that in FIG. 1 are denoted by the same reference characters, and description thereof will be omitted.

In a PDP driver device 1x of the second embodiment, grooves 8x, which function as airflow paths in a heat dissipating body 4x, are formed in the middle of two long sides of a rectangular recess 41. It is desirable that the grooves 8x have a substantially V-shaped cross section, like the grooves 8 of the heat dissipating body 4 described in the first embodiment.

Thus, even if grease enters one of the grooves 8x formed in the heat dissipating body 4x, the other groove 8x, which faces the one groove 8x, can reliably serve as an airflow path, whereby high reliability can be ensured. Note that second grooves 82 of both grooves 8x extend from first grooves 81 to the same edge of the heat dissipating body 4 so as to connect to the outside. However, the one groove 8x and the other groove 8x may be formed so that the second grooves 82 extend to different edges of the heat dissipating body 4 from each other.

### Third Embodiment

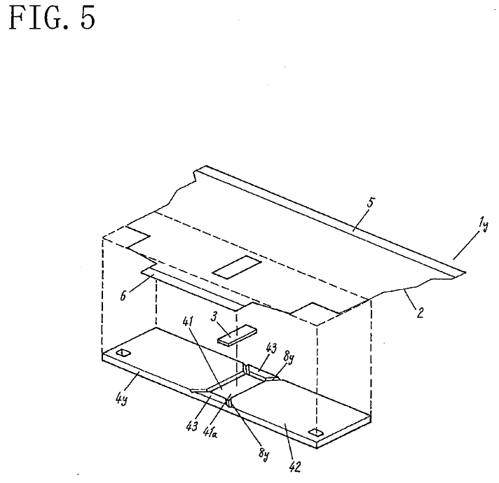

A PDP driver device according to a third embodiment of the present invention will be described with reference to FIG. 5. FIG. 5 is a perspective view of the PDP driver device as an example of a driver module according to the third embodiment of the present invention. Note that, in FIG. 5, components having the same configuration as that in FIG. 1 are denoted by the same reference characters, and description thereof will be omitted.

In a PDP driver device 1y of the third embodiment, grooves 8y, which function as airflow paths in a heat dissipating body 4y, are formed so as to extend radially outward in four directions from the four corners of a rectangular recess 41. Advantages similar to those of the first embodiment can be obtained even if the grooves 8y are formed in the heat dissipating body 4y in this manner.

Since the grooves 8y extend radially outward in the four directions from the four corners of the rectangular recess 41, small regions 43, each surrounded by a shorter side of the recess 41 and two grooves 8y, are formed in the bonding surface 42 of the heat dissipating body 4y. If these regions 43 are so small that their bonding areas with the flexible substrate 2 are not large enough, the heat dissipating body 4y can delaminate from the flexible substrate 2, and adhesion therebetween cannot be ensured. In such a case, the grooves may be formed so as to first extend from the four corners of the recess 41 along the longitudinal direction of the heat dissipating body 4y, and then to the edges of the heat dissipating body 4y. Large regions 43 can be reliably formed in this manner.

Although the first to third embodiments of the present invention are described above, the present invention is not limited to these embodiments. For example, although the grooves 8, 8x, 8y formed in the bonding surface 42 function as airflow paths in the first to third embodiments, advantages similar to those of the grooves 8, 8x, 8y can be obtained by providing at least two tunnel-like through holes that extend from the inner peripheral wall of the recess to the outer peripheral wall of the heat dissipating body.

Although four grooves 8, 8y and two grooves 8x are provided in the above embodiments, the number of grooves may be three, or five or more. In this case as well, it is desirable that at least two grooves be positioned so as to face each other on the inner wall surface of the recess 41.

Although the PDP driver device 1, 1x, 1y provided with one semiconductor device 3 is described as an example in the above embodiments, similar advantages can also be obtained by PDP driver devices provided with two or more semiconductor devices 3, if two or more airflow paths are formed in each of the recesses configured to accommodate the semiconductor devices 3. In this case, the airflow path may connect to another airflow path at an intermediate position between the recess and the outside, as long as the space in the recess communicates with the outside.

### INDUSTRIAL APPLICABILITY

Since the present invention is capable of ensuring high reliability, the present invention is preferable for, e.g., driver module structures that include a flexible substrate having a semiconductor substrate placed thereon, and a heat dissipating body configured to dissipate heat that is generated by the semiconductor device.

1. A driver module structure, comprising:
a flexible substrate having an interconnect pattern;
a semiconductor device placed on the flexible substrate; and
a heat dissipating body having a recess configured to accommodate the semiconductor device, wherein
the heat dissipating body is provided with at least two airflow paths that connect a space in the recess to outside.

2. The driver module structure of claim 1, wherein
the at least two airflow paths are positioned so as to face each other on an inner peripheral surface of the recess.

3. The driver module structure of claim 1 or 2, wherein
the airflow paths are grooves having a substantially V-shaped cross section.

4. The driver module structure of claim 2, wherein
the airflow paths are grooves having a substantially V-shaped cross section.
